(19) United States
(12) Patent Application Publication
(10) Pub. No.: US 2026/0035234 A1
(43) Pub. Date: Feb. 5, 2026

(54) MICROELECTROMECHANICAL STRUCTURE WITH IMPROVED MECHANICAL ROBUSTNESS

(71) Applicant: STMicroelectronics International N.V., Geneva (CH)

(72) Inventors: Patrick FEDELI, Senago (IT); Paola CARULLI, Milano (IT); Luca Giuseppe FALORNI, Limbiate (MB) (IT); Federico MORELLI, Milano (MI) (IT)

(73) Assignee: STMicroelectronics International N.V., Geneva (CH)

(21) Appl. No.: 19/278,464

(22) Filed: Jul. 23, 2025

(30) Foreign Application Priority Data
Jul. 30, 2024 (IT) 102024000017707

(51) Int. Cl. B81B 3/00

(52) U.S. Cl. CPC B81B 3/0072; B81B 2201/0235; B81B 2201/0242; B81B 2203/0154; B81B 2203/0307; B81B 2203/056; B81B 2203/058

(57) ABSTRACT

A microelectromechanical structure has a mobile-mass with a main extension in a horizontal plane, defined by first and second horizontal axes, and having an internal window. The mobile-mass is elastically coupled to a central anchoring structure, arranged centrally with respect to the window, by an elastic structure, so that it can perform a first rotation outside the horizontal plane and a second rotation in the horizontal plane. The elastic structure has a first symmetry-axis parallel to the first horizontal-axis and a second symmetry-axis parallel to the second horizontal-axis, and has first and second elastic elements arranged in a central position of the window, on opposite sides with respect to the first symmetry-axis. The first and second elastic elements have the shape of an “H” in the horizontal plane, mirrored with respect to the first symmetry-axis and face each other at a separation distance along the second horizontal-axis.

### PRIORITY CLAIM

This application claims the priority benefit of Italian Application for Patent No. 102024000017707 filed on Jul. 30, 2024, the content of which is hereby incorporated by reference in its entirety to the maximum extent allowable by law.

### TECHNICAL FIELD

This disclosure relates to a microelectromechanical structure with improved mechanical robustness.

### BACKGROUND

As is known, microelectromechanical structures (of a MicroElectroMechanical System (MEMS)-type), made with semiconductor technology, are used to provide several electronic devices, such as inertial sensing devices (e.g., gyroscopes or accelerometers), resonators, actuators, or the like.

For instance, microelectromechanical structures are known to have a mobile mass (e.g., a sensing mass) configured to perform a first rotational movement in a plane of main extension and a second rotational movement outside the same plane.

FIG. 1 schematically illustrates a microelectromechanical structure of this type, generally indicated by reference numeral 1, for example, designed to provide an accelerometer or a gyroscope (having one or more sensing axes).

The microelectromechanical structure 1 comprises a mobile mass 2 (in particular, a sensing mass) having a main extension in a horizontal plane xy, defined by a first and a second horizontal axis x, y, and having a smaller extension (substantially negligible compared to the aforementioned main extension) along a vertical axis z, orthogonal to the horizontal plane xy.

In the example, the mobile mass 2 has, in the aforementioned horizontal plane xy, a generally rectangular shape, extending along the first horizontal axis x and along the second horizontal axis y, perpendicular to the first axis, with dimensions determined by design specifications and constraints.

In a manner not illustrated herein, the mobile mass 2 is arranged suspended above a substrate of the microelectromechanical structure 1, having an upper surface (facing the mobile mass 2) where fixed sensing electrodes (capacitively coupled to the same mobile mass 2) are typically formed.

The mobile mass 2 internally defines a window 4 that divides it into a first and a second portion (2a, 2b), which may have a mass distribution that is symmetrical (such as in the case illustrated) or asymmetrical (e.g., with the first portion 2a having an extension along the first horizontal axis x greater than the corresponding extension of the second portion 2b).

The mobile mass 2 is elastically coupled to a central anchor 5 by means of a first and a second elastic element (6a, 6b). This central anchor 5 has, for example, a pillar shape, is arranged centrally with respect to the window 4, and is coupled at the bottom to the substrate in an integral manner (in a manner not illustrated here).

The first and second elastic elements (6a, 6b) are of the torsional type, have a linear extension along the second horizontal axis y of the horizontal plane xy, and are aligned along the same horizontal axis y, defining a rotation axis A for the mobile mass 2 (parallel to the second horizontal axis y).

In particular, the mobile mass 2 is able to move (e.g., dragged by a driving mass, not illustrated, or due to inertial effects in the presence of an acceleration or another external stimulus acting along the vertical axis z) with a first rotational movement around the aforementioned rotation axis A, in particular a tilting or teeter-totter movement with a central fulcrum at the central anchor 5.

In a manner not illustrated, the aforementioned fixed sensing electrodes typically comprise a first and a second fixed electrode, arranged below the mobile mass 2, on opposite sides with respect to the window 4 (a first fixed electrode arranged below the first portion 2a and a second fixed electrode arranged below the second portion 2b of the mobile mass 2, forming a pair of sensing capacitors).

The aforementioned rotation of the mobile mass 2 around the rotation axis A therefore determines a movement of the mobile mass 2 towards/away from a first fixed electrode and a corresponding movement of the same mobile mass 2 away from/towards a second fixed electrode, thereby causing a differential capacitive variation of the aforementioned sensing capacitors, indicative of a quantity to be sensed (e.g., an angular velocity, an acceleration, or another external stimulus).

The mobile mass 2 is also configured to move (e.g., dragged by a driving mass, not illustrated) with a second rotational movement in the horizontal plane xy, in particular around an axis parallel to the vertical axis z and passing through the aforementioned central anchor 5 (e.g., at a corresponding geometric center O).

In the microelectromechanical structure 1, the aforementioned first and second elastic elements (6a, 6b) are therefore required to be suitably configured and sized to allow both rotational movements (outside the horizontal plane xy and in the horizontal plane xy) of the mobile mass 2.

A possible issue with a microelectromechanical structure of this type is its robustness against shocks, i.e., against impulsive impacts or vibrations, which may, in particular, occur along the direction of the vertical axis z, for example, due to falls or impacts.

In particular, the shocks to which the microelectromechanical structure may be subjected may also be very high, for example, up to 103-105 g of acceleration. Such shocks may produce significant deformation of the elastic elements, resulting in high stresses, which may also be higher than the mechanical breaking limit of the material of the microelectromechanical structure (typically silicon) and possibly cause damage to the same microelectromechanical structure.

In particular, in the case of the microelectromechanical structure 1 of FIG. 1, maximum stress due to the aforementioned shocks typically occurs at the coupling zone of the first and second elastic elements (6a, 6b) to the central anchor 5.

A known solution to avoid possible breakdowns involves inserting stoppers into the microelectromechanical structure in suitable positions, at a given distance from the mobile mass, to limit the range of displacement in the event of a shock.

However, the introduction of such stoppers may complicate the design of the microelectromechanical structure. Furthermore, the distance between the stoppers and the mobile mass is typically imposed by the manufacturing process and therefore cannot be adjusted as desired.

Another solution to limit the issues associated with shocks involves suitably designing the elastic elements of the microelectromechanical structure. The design of the elastic elements strongly influences the stress level (i.e., the force per unit area that the material experiences when subjected to shock) and therefore the intrinsic robustness and functionality of the entire microelectromechanical structure.

The present Applicant has, however, found that the layouts typically used for manufacturing such elastic elements allow for suitable robustness solely for mobile masses with low inertia (e.g., for so-called “consumer” products or applications).

At least for certain applications, there is a clear need to provide solutions that increase the mechanical robustness of microelectromechanical structures against shocks.

### SUMMARY

The present solution generally aims to overcome the limitations of known-type systems and to provide an answer to the aforementioned need.

According to the present solution, a microelectromechanical structure is therefore provided, as defined in the attached claims.

For example, a microelectromechanical structure includes a mobile mass having a main extension in a horizontal plane, defined by a first horizontal axis and a second horizontal axis, and having internally a window. The mobile mass is elastically coupled to a central anchoring structure, arranged centrally with respect to the window, by an elastic structure configured so that the mobile mass is able to perform a first rotation movement outside the horizontal plane and a second rotation movement in the horizontal plane. The elastic structure has a first median or symmetry axis parallel to the first horizontal axis and a second median or symmetry axis parallel to the second horizontal axis and includes a first elastic element and a second elastic element arranged centrally to the window, on opposite sides with respect to the first median or symmetry axis. The first and second elastic elements have substantially a shape of an H in the horizontal plane, specularly (e.g., mirrored) with respect to the first median or symmetry axis and facing each other at a certain separation distance along the second horizontal axis.

The first and second elastic elements may be separated along the second horizontal axis by a gap having a substantially rectangular shape in the horizontal plane. The gap may be elongated along the first horizontal axis and thin, having a greater extension along the first horizontal axis and a smaller extension along the second horizontal axis. Each of the first elastic element and second elastic element may include a first lateral portion and a second lateral portion, having a substantially rectangular shape in the horizontal plane, with an extension parallel to the first horizontal axis, and a central portion which centrally couples the first and second lateral portions, having a substantially rectangular shape in the horizontal plane, with an extension parallel to the second horizontal axis.

The central portions of the first and second elastic elements may be aligned with each other and jointly define a rotation axis for the first rotation movement of the mobile mass outside the horizontal plane. The first lateral portions of the first and second elastic elements may have respective ends coupled to the mobile mass on opposite sides with respect to the rotation axis, and the second lateral portions of the first and second elastic elements may have respective ends coupled to the central anchoring structure.

The central anchoring structure may include a first anchor and a second anchor arranged in a central position on opposite sides and specularly (e.g., mirrored) with respect to the rotation axis, facing each other at a certain separation distance along the first horizontal axis. The first anchor may have the shape of a C and the second anchor may have a corresponding shape of an inverted-C, specularly (e.g., mirrored) with respect to the first anchor with respect to the rotation axis. The first and second anchors may define as a whole a central recess. The second lateral portions of the first and second elastic elements may be arranged in the central recess and have respective ends coupled to the first and respectively the second anchor of the central anchoring structure, at the central recess.

The mobile mass may be configured to rotate with a first rotation movement outside the horizontal plane around the rotation axis, mainly due to torsion of the central portions of the first and second elastic elements, and to rotate with a second rotation movement in the horizontal plane, around an axis parallel to a vertical axis, orthogonal to the horizontal plane, mainly due to bending of the central portions of the first and second elastic elements in the horizontal plane. The configuration of the first and second elastic elements may be such that the corresponding second lateral portions do not contribute substantially to defining operating frequencies and modes for the first and second rotation movements. The gap may be configured to decouple the second lateral portions in a direction of the second horizontal axis.

The elastic structure may be configured to reduce effects of shocks acting along a vertical axis, orthogonal to the horizontal plane, on the microelectromechanical structure. The structure may define a sensing structure of a gyroscope or a MEMS accelerometer.

A gyroscope may include a structure as described above. A MEMS accelerometer may include a structure as described above.

In another embodiment, a microelectromechanical structure includes a mobile mass having a main extension in a horizontal plane defined by a first horizontal axis and a second horizontal axis, the mobile mass having a window formed therein, a central anchoring structure arranged centrally with respect to the window, and an elastic structure elastically coupling the mobile mass to the central anchoring structure and configured to enable the mobile mass to perform a first rotational movement outside the horizontal plane and a second rotational movement within the horizontal plane. The elastic structure has a first symmetry axis parallel to the first horizontal axis and a second symmetry axis parallel to the second horizontal axis, and includes a first elastic element and a second elastic element arranged centrally within the window on opposite sides of the first symmetry axis, each elastic element having substantially an H-shape in the horizontal plane and being positioned specularly (e.g., mirrored) with respect to the first symmetry axis and facing each other at a separation distance along the second horizontal axis. Each of the first and second elastic elements includes a first lateral portion and a second lateral portion, each having a substantially rectangular shape in the horizontal plane with an extension parallel to the first horizontal axis, and a central portion centrally coupling the first and second lateral portions, the central portion having a substantially rectangular shape in the horizontal plane with an extension parallel to the second horizontal axis. The central portions of the first and second elastic elements are aligned with each other to jointly define a rotation axis for the first rotational movement of the mobile mass outside the horizontal plane. The first lateral portions of the first and second elastic elements have respective ends coupled to the mobile mass on opposite sides of the rotation axis, and the second lateral portions of the first and second elastic elements have respective ends coupled to the central anchoring structure.

The central anchoring structure may include a first anchor and a second anchor arranged centrally on opposite sides of the rotation axis in a specular configuration, the first and second anchors facing each other with a separation distance along the first horizontal axis. The first anchor may have a C-shape and the second anchor may have a corresponding inverted C-shape positioned specularly (e.g., mirrored) with respect to the first anchor with respect to the rotation axis, and the first and second anchors may collectively define a central recess. The second lateral portions of the first and second elastic elements may be positioned within the central recess and have respective ends coupled to the first anchor and the second anchor of the central anchoring structure at the central recess.

In yet another embodiment, a microelectromechanical structure includes a mobile mass having a main extension in a horizontal plane and having a window formed therein, a central anchoring structure positioned within the window, and an elastic structure coupling the mobile mass to the central anchoring structure and configured to enable the mobile mass to perform rotational movement outside the horizontal plane and rotational movement within the horizontal plane. The elastic structure includes a first elastic element and a second elastic element each having substantially an H-shape in the horizontal plane, the first and second elastic elements being positioned on opposite sides of a symmetry axis and separated by a gap to provide improved mechanical robustness against shock.

Each H-shaped elastic element may include a first lateral portion and a second lateral portion having extensions in a first direction, and a central portion extending in a second direction perpendicular to the first direction and coupling the first and second lateral portions. The central portions may jointly define a rotation axis for the rotational movement outside the horizontal plane. The first lateral portions may be coupled to the mobile mass on opposite sides of the rotation axis, and the second lateral portions may be coupled to the central anchoring structure. The second lateral portions may have a thickness smaller than a thickness of the first lateral portions to reduce stress concentration during shock loading. The gap separating the first and second elastic elements may decouple the elastic elements to distribute stress uniformly during shock loading and prevent stress concentrations that could exceed material breakdown limits.

### BRIEF DESCRIPTION OF THE DRAWINGS

For a better understanding of this disclosure, a preferred embodiment thereof is now described, purely by way of non-limiting example and with reference to the attached drawings, wherein:

FIG. 1 shows a schematic perspective plan view of a microelectromechanical structure of a known type;

FIG. 2A shows a schematic plan view of a microelectromechanical structure;

FIG. 2B shows an enlargement of a portion of the microelectromechanical structure of FIG. 2A, relating to an elastic and anchoring structure;

FIG. 3 shows the result of a simulation, with respect to the portion of interest of the elastic and anchoring structure, where expected stress generated by a mechanical strain in the event of an impact are highlighted; and

FIGS. 4A and 4B show plots relating to the trend of the stress acting on the microelectromechanical structure as a function of time, at the points of interest, in response to an initial impulsive shock.

### DETAILED DESCRIPTION

As will be described below, one aspect of the present solution involves providing an optimized elastic structure for the elastic coupling of at least one mobile mass of a microelectromechanical structure to a corresponding anchor, in order to reduce stresses that may occur due to a shock (e.g., due to a fall, an impact, or a similar mechanical strain), particularly in the direction of a vertical axis orthogonal to a main extension plane of the same microelectromechanical structure.

The aforementioned elastic structure is advantageously designed so as not to significantly impact the operating modes of the microelectromechanical structure, particularly not to alter its corresponding main operating frequencies (e.g., one or more driving or sensing frequencies).

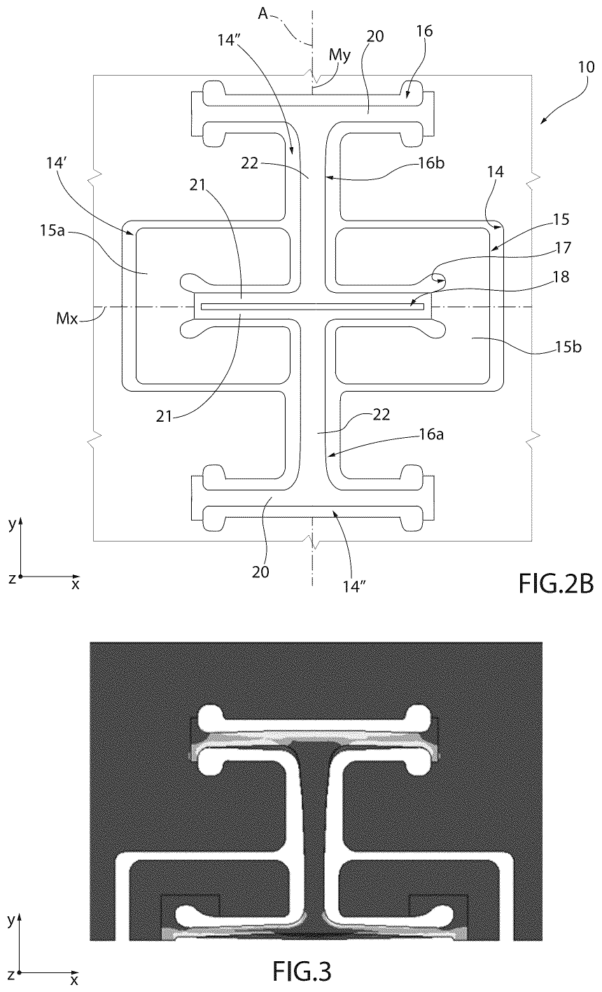

FIGS. 2A and 2B show a microelectromechanical structure 10 according to one embodiment of the present solution, for example, designed to be part of a gyroscope or an accelerometer, or in general, an inertial sensor (without, however, the present discussion being limited to such exemplary applications).

In a manner substantially similar to what has been previously discussed, the microelectromechanical structure 10, made using manufacturing processes (of a known type, not described in detail herein) of semiconductor material, in particular silicon, comprises a mobile mass 12 (in particular, a sensing mass) having a main extension in a horizontal plane xy, defined by a first and a second horizontal axis x, y, and, in a manner not illustrated herein, having a smaller extension (substantially negligible with respect to the aforementioned main extension) along a vertical axis z, orthogonal to the horizontal plane xy. In the example, the mobile mass 12 has a generally rectangular shape, elongated in this case along the second horizontal axis y.

The mobile mass 12 also internally defines a window 14, which divides it into a first and a second portion (12a, 12b) and is elastically coupled to a central anchoring structure 15, arranged centrally with respect to the window 14, by means of an elastic structure 16.

As will be described in detail, this elastic structure 16 generally defines a rotation axis A, in this case parallel to the second horizontal axis y, for the mobile mass 12. The same mobile mass 12 may move (e.g., dragged by a driving mass, not illustrated, or due to inertial effects in the presence of an external acceleration or another stimulus quantity acting along the vertical axis z) with a first rotational movement, in particular a tilting or teeter-totter movement with a central fulcrum, around the aforementioned rotation axis A.

The same mobile mass 12 may also move (e.g., dragged by a driving mass, not illustrated) with a second rotational movement in the horizontal plane xy, in particular around an axis parallel to the vertical axis z and passing through a geometric center O of the aforementioned central anchoring structure 15.

The elastic structure 16 has a first median or symmetry axis Mx parallel to the aforementioned first horizontal axis x and a second median or symmetry axis My parallel to the aforementioned second horizontal axis y. (In this embodiment, the microelectromechanical structure 10 is entirely symmetrical with respect to the first and second median or symmetry axes Mx, My.) The aforementioned geometric center O is the intersection between the same first and second median or symmetry axes Mx, My.

The central anchoring structure 15 comprises a first and a second anchor (15a, 15b) arranged in a central position on opposite sides and specularly (e.g., mirrored) with respect to the rotation axis A (or to the second median or symmetry axis My), facing each other at a certain separation distance (considered along the first horizontal axis x).

In particular, in the embodiment illustrated in FIGS. 2A and 2B, the first anchor 15a has a “C” shape, and the second anchor 15b has a corresponding “inverted-C” shape, specularly (e.g., mirrored) with respect to the first anchor 15a with respect to the rotation axis A (and to the second median or symmetry axis My). The first and second anchors 15a, 15b define, as a whole, a central recess 17, arranged at the aforementioned first median or symmetry axis Mx.

The elastic structure 16 comprises a first and a second elastic element (16a, 16b) arranged in a central position, on opposite sides and specularly (e.g., mirrored) with respect to the first median or symmetry axis Mx, facing each other at a certain separation distance (considered along the second horizontal axis y).

In detail, in the embodiment illustrated in FIGS. 2A and 2B, the first and second elastic elements (16a, 16b) have the shape of an “H,” specularly (e.g., mirrored) with respect to the first median or symmetry axis Mx, and are separated along the second horizontal axis y by a slot or gap 18, having a substantially rectangular shape in the horizontal plane xy, elongated along the first horizontal axis x, and very thin (i.e., having a much smaller extension along the second horizontal axis y).

In general, the thickness of such a gap 18 (considered along the second horizontal axis y) may be sized as the minimum value allowed by the technological manufacturing process (e.g., by corresponding masking and etching steps) or to a slightly higher value (e.g., in cases where it is required to ensure a driving movement around the z-axis without generating mechanical interferences in corresponding portions of the elastic elements 21). In general, the aforementioned sizing of the gap 18 allows the stiffness of the rotational driving movement around the z-axis not to be excessively altered.

In greater detail (and as illustrated in an enlarged manner in FIG. 2B), each of the first and second elastic elements (16a, 16b) comprises a first and a second lateral portion (20, 21), having a substantially rectangular shape in the horizontal plane xy, with an extension parallel to the first horizontal axis x, and a central portion 22, which centrally couples the first and second lateral portions (20, 21), having a substantially rectangular shape in the horizontal plane xy, with an extension parallel to the second horizontal axis y.

In particular, the central portions 22 of the first and second elastic elements (16a, 16b) are aligned with each other and jointly define the aforementioned rotation axis A for the mobile mass 12.

Furthermore, the first lateral portions 20 of the first and second elastic elements (16a, 16b) have respective ends coupled to the mobile mass 12 on opposite sides with respect to the rotation axis A, respectively to the first and second portions (12a, 12b) of the same mobile mass 12.

The second lateral portions 21 of the first and second elastic elements (16a, 16b) have respective ends coupled to the central anchoring structure 15, in particular to the first and second anchors (15a, 15b), at the central recess 17.

The first and second lateral portions (20, 21) may have, as in the embodiment illustrated in FIGS. 2A and 2B, substantially corresponding extensions along the first horizontal axis x; alternatively, the same first and second lateral portions (20, 21) may have different extensions along the first horizontal axis x.

In a possible embodiment (illustrated in FIGS. 2A and 2B), the central portions 22 of the first and second elastic elements 16a, 16b have a thickness, considered along the first horizontal axis x, greater than the respective thickness of both the first and second lateral portions 20, 21, considered along the second horizontal axis y. Furthermore, the second lateral portion 21 of the first and second elastic elements 16a, 16b has a thickness smaller than the respective thickness of the first lateral portion 20. The second lateral portion 21 is therefore thinner than the first lateral portion 20 and also thinner than the central portion 22.

In the embodiment illustrated in FIGS. 2A and 2B, the aforementioned window 14 has a shape that follows and replicates the shape of the elastic structure 16 and the anchoring structure 15, thus having a substantially rectangular central opening portion 14′ with an extension along the first horizontal axis x and lateral opening portions 14″ having a “T” shape.

During operation, the mobile mass 12 is able to rotate outside the horizontal plane xy around the rotation axis A, mainly due to the torsion of the central portions 22 of the first and second elastic elements 16a, 16b. The first and second lateral portions 20, 21 of the same first and second elastic elements 16a, 16b are rigid to bending outside the horizontal plane xy during rotation around the rotation axis A.

Furthermore, the same mobile mass 12 is able to rotate in the horizontal plane xy around an axis parallel to the vertical axis z passing through the center O, mainly due to the bending of the central portions 22 of the first and second elastic elements 16a, 16b in the horizontal plane xy. The first and second lateral portions 20, 21 of the same elastic elements 16a, 16b are rigid to bending in the horizontal plane xy.

In particular, the configuration of the elastic elements 16a, 16b is such that the corresponding second lateral portions 21 do not contribute substantially to defining the operating frequencies and modes for the aforementioned first and second rotation movements.

The second lateral portions 21, separated by the gap 18 (which decouples the same second lateral portions 21 in the direction of the second horizontal axis y), conversely allow for reducing the effects of shocks, particularly shocks acting along the vertical axis z.

In this regard, FIG. 3 shows the manner in which stresses resulting from a shock along the vertical axis z discharge uniformly along the entire extension of the first and second lateral portions 20, 21, without creating dangerous stress concentrations that might exceed the structural limits of the material of the elastic elements, typically silicon.

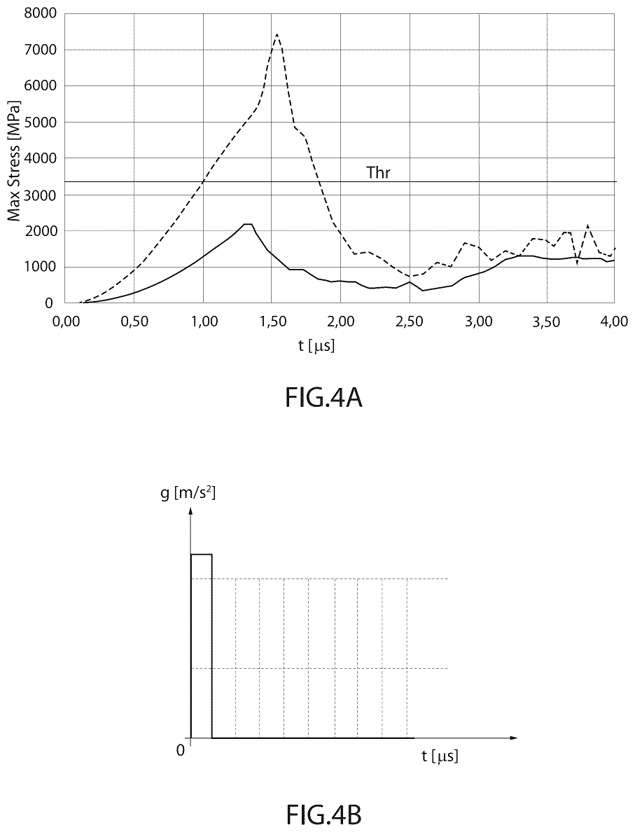

Furthermore, FIG. 4A shows, in solid line, the trend of a maximum stress value (“Max stress”) acting on the microelectromechanical structure 10 (in particular on the corresponding elastic elements) as a function of time, in response to an impulsive shock at an initial time, as shown in FIG. 4B.

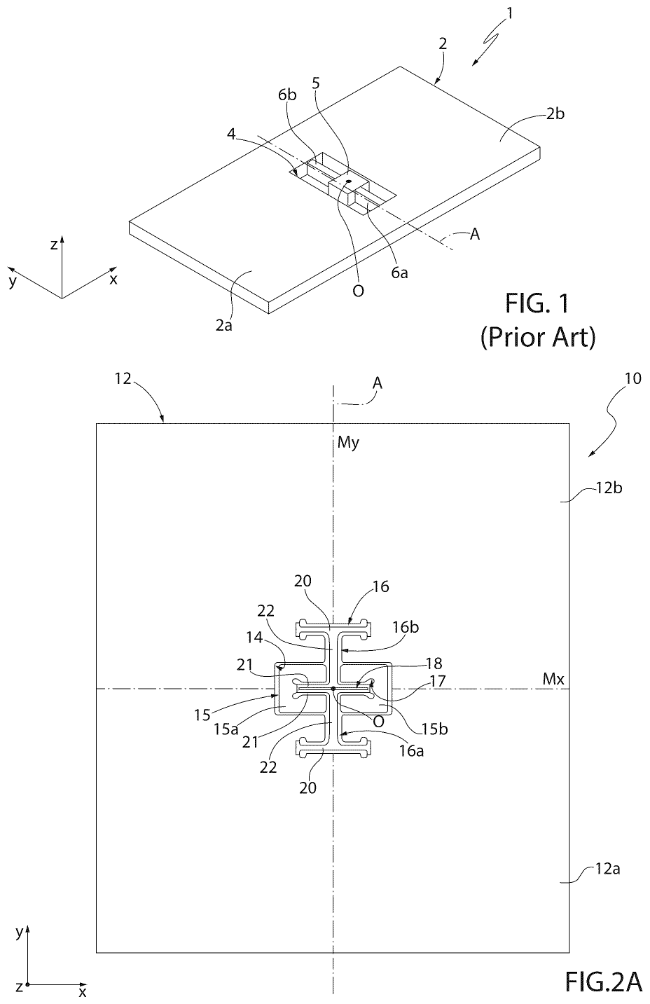

In particular, in FIG. 4A, this trend is compared with a corresponding trend of the stress that may occur in a known microelectromechanical structure (for example, of the type described with reference to FIG. 1), which is depicted in a dashed line.

It is apparent that the described solution significantly reduces the maximum peak of the achievable stress, which is substantially lower than a material breakdown threshold Thr. Conversely, in the known solution, the same shock may instead cause the material breakdown threshold Thr to be exceeded.

The advantages of the proposed solution are clear from the preceding description.

In any case, it is emphasized that the described solution significantly reduces the stresses that may occur due to shocks, particularly those acting in the direction of the vertical axis, without at the same time affecting the operating conditions of the microelectromechanical structure, particularly without altering the corresponding modes or operating frequencies.

As previously indicated, the elastic elements that couple the mobile mass to the anchor integral to the substrate are configured and sized to increase robustness without modifying the operating modes.

Furthermore, the manufacturing of the described structure does not require substantial modifications to the manufacturing process, particularly without requiring additional processing steps or different treatments.

Finally, it is clear that modifications and variations may be made to what has been described and illustrated herein without departing from the scope of this disclosure, as defined in the attached claims.

In particular, it is emphasized that the described solution may find advantageous application regardless of the actual implementation of the microelectromechanical structure or the electronic device of which the same microelectromechanical structure is part (for example, a sensor device such as an accelerometer or a gyroscope, an actuator, or the like).

In particular, it is emphasized that the microelectromechanical structure may, for example, include a greater number of mobile masses, each or only some of which may be coupled to a corresponding anchoring structure by means of an elastic coupling structure similar to that previously described in order to reduce mechanical stresses.

Furthermore, the microelectromechanical structure may comprise one or more driving masses suitably configured and coupled to the mobile sensing masses to cause their movement (for example, according to the first and/or second rotation movement previously described).

For example, the microelectromechanical structure might be part of a MEMS gyroscope, as described in the European patent application 24177019.7 filed on May 21, 2024 (incorporated herein by reference).

In such a MEMS gyroscope, of the triaxial type, two mobile masses arranged centrally to the microelectromechanical structure (able to perform the aforementioned first and second rotation movements, outside the horizontal plane and in the horizontal plane) may advantageously be elastically coupled to a respective anchor through an clastic coupling solution similar to that previously described, in order to reduce the stress in the event of a shock.

1. A microelectromechanical structure, comprising:
a mobile mass having a main extension in a horizontal plane, defined by a first horizontal axis and a second horizontal axis, and having internally a window, said mobile mass being elastically coupled to a central anchoring structure, arranged centrally with respect to the window, by an elastic structure configured so that said mobile mass is able to perform a first rotation movement outside said horizontal plane and a second rotation movement in said horizontal plane;
wherein said elastic structure has a first median or symmetry axis parallel to said first horizontal axis and a second median or symmetry axis parallel to said second horizontal axis and comprises a first elastic element and a second elastic element arranged centrally to said window, on opposite sides with respect to the first median or symmetry axis,
wherein said first and second elastic elements have substantially a shape of an “H” in the horizontal plane, mirrored with respect to said first median or symmetry axis and facing each other at a certain separation distance along the second horizontal axis.

2. The microelectromechanical structure according to claim 1, wherein said first and second elastic elements are separated along the second horizontal axis by a gap having a substantially rectangular shape in the horizontal plane.

3. The microelectromechanical structure according to claim 2, wherein said gap is elongated along the first horizontal axis and thin, having a greater extension along said first horizontal axis and a smaller extension along the second horizontal axis.

4. The microelectromechanical structure according to claim 2, wherein each of said first elastic element and second elastic element comprises a first lateral portion and a second lateral portion, having a substantially rectangular shape in the horizontal plane, with an extension parallel to the first horizontal axis, and a central portion which centrally couples the first and second lateral portions, having a substantially rectangular shape in the horizontal plane, with an extension parallel to the second horizontal axis.

5. The microelectromechanical structure according to claim 4, wherein the central portions of the first and second elastic elements are aligned with each other and jointly define a rotation axis for said first rotation movement of the mobile mass outside the horizontal plane.

6. The microelectromechanical structure according to claim 5, wherein said first lateral portions of the first and second elastic elements have respective ends coupled to the mobile mass on opposite sides with respect to the rotation axis; and the second lateral portions of the first and second elastic elements have respective ends coupled to the central anchoring structure.

7. The microelectromechanical structure according to claim 5, wherein said central anchoring structure comprises a first anchor and a second anchor arranged in a central position on opposite sides and mirrored with respect to the rotation axis, facing each other at a certain separation distance along the first horizontal axis.

8. The microelectromechanical structure according to claim 7, wherein said first anchor has the shape of a “C” and the second anchor has a corresponding shape of an “inverted-C”, mirrored with respect to the first anchor with respect to the rotation axis; and wherein said first and second anchors define as a whole a central recess.

9. The microelectromechanical structure according to claim 8, wherein the second lateral portions of the first and second elastic elements are arranged in said central recess and have respective ends coupled to the first and respectively the second anchor of the central anchoring structure, at the central recess.

10. The microelectromechanical structure according to claim 5, wherein said mobile mass is configured to rotate with a first rotation movement outside the horizontal plane around the rotation axis, mainly due to torsion of the central portions of said first and second elastic elements; and to rotate with a second rotation movement in the horizontal plane, around an axis parallel to a vertical axis, orthogonal to said horizontal plane, mainly due to bending of the central portions of said first and second elastic elements in the horizontal plane.

11. The microelectromechanical structure according to claim 10, wherein the configuration of said first and second elastic elements is such that the corresponding second lateral portions do not contribute substantially to defining operating frequencies and modes for said first and second rotation movements.

12. The microelectromechanical structure according to claim 11, wherein said gap is configured to decouple said second lateral portions in a direction of the second horizontal axis.

13. The microelectromechanical structure according to claim 1, wherein said elastic structure is configured to reduce effects of shocks acting along a vertical axis, orthogonal to said horizontal plane, on said microelectromechanical structure.

14. The microelectromechanical structure according to claim 1, wherein the structure defines a sensing structure of a gyroscope or a MEMS accelerometer.

15. A gyroscope comprising a structure according to claim 1.

16. A MEMS accelerometer comprising a structure according to claim 1.

17. A microelectromechanical structure, comprising:
a mobile mass having a main extension in a horizontal plane defined by a first horizontal axis and a second horizontal axis, said mobile mass having a window formed therein;
a central anchoring structure arranged centrally with respect to the window; and
an elastic structure elastically coupling the mobile mass to the central anchoring structure and configured to enable the mobile mass to perform a first rotational movement outside the horizontal plane and a second rotational movement within the horizontal plane;
wherein the elastic structure has a first symmetry axis parallel to the first horizontal axis and a second symmetry axis parallel to the second horizontal axis, and comprises a first elastic element and a second elastic element arranged centrally within the window on opposite sides of the first symmetry axis, each elastic element having substantially an H-shape in the horizontal plane and being positioned mirrored with respect to the first symmetry axis and facing each other at a separation distance along the second horizontal axis;
wherein each of the first and second elastic elements comprises:
a first lateral portion and a second lateral portion, each having a substantially rectangular shape in the horizontal plane with an extension parallel to the first horizontal axis, and
a central portion centrally coupling the first and second lateral portions, the central portion having a substantially rectangular shape in the horizontal plane with an extension parallel to the second horizontal axis;
wherein the central portions of the first and second elastic elements are aligned with each other to jointly define a rotation axis for the first rotational movement of the mobile mass outside the horizontal plane;
wherein the first lateral portions of the first and second elastic elements have respective ends coupled to the mobile mass on opposite sides of the rotation axis; and
wherein the second lateral portions of the first and second elastic elements have respective ends coupled to the central anchoring structure.

18. The microelectromechanical structure according to claim 5, wherein the central anchoring structure comprises a first anchor and a second anchor arranged centrally on opposite sides of the rotation axis in a specular configuration, the first and second anchors facing each other with a separation distance along the first horizontal axis.

19. The microelectromechanical structure according to claim 18, wherein the first anchor has a C-shape and the second anchor has a corresponding inverted C-shape positioned mirrored with respect to the first anchor with respect to the rotation axis, and wherein the first and second anchors collectively define a central recess.

20. The microelectromechanical structure according to claim 19, wherein the second lateral portions of the first and second elastic elements are positioned within the central recess and have respective ends coupled to the first anchor and the second anchor of the central anchoring structure at the central recess.

21. A microelectromechanical structure, comprising:
a mobile mass having a main extension in a horizontal plane and having a window formed therein;
a central anchoring structure positioned within the window; and
an elastic structure coupling the mobile mass to the central anchoring structure and configured to enable the mobile mass to perform rotational movement outside the horizontal plane and rotational movement within the horizontal plane;
wherein the elastic structure comprises a first elastic element and a second elastic element each having substantially an H-shape in the horizontal plane, the first and second elastic elements being positioned on opposite sides of a symmetry axis and separated by a gap to provide improved mechanical robustness against shock.

22. The microelectromechanical structure of claim 21, wherein each H-shaped elastic element comprises:
a first lateral portion and a second lateral portion having extensions in a first direction; and
a central portion extending in a second direction perpendicular to the first direction and coupling the first and second lateral portions;
wherein the central portions jointly define a rotation axis for the rotational movement outside the horizontal plane.

23. The microelectromechanical structure of claim 22, wherein:
the first lateral portions are coupled to the mobile mass on opposite sides of the rotation axis; and
the second lateral portions are coupled to the central anchoring structure.

24. The microelectromechanical structure of claim 23, wherein the second lateral portions have a thickness smaller than a thickness of the first lateral portions to reduce stress concentration during shock loading.

25. The microelectromechanical structure of claim 21, wherein the gap separating the first and second elastic elements decouples the elastic elements to distribute stress uniformly during shock loading and prevent stress concentrations that could exceed material breakdown limits.
